(19) United States
(12) Patent Application Publication
(10) Pub. No.: US 2014/0103505 A1
(43) Pub. Date: Apr. 17, 2014

(54) DIE DOWN INTEGRATED CIRCUIT PACKAGE WITH INTEGRATED HEAT SPREADER AND LEADS

(71) Applicant: BROADCOM CORPORATION, Irvine, CA (US)

(72) Inventors: Sam Ziqun Zhao, Irvine, CA (US); Rezaur Rahman Khan, Rancho Santa Margarita, CA (US)

(73) Assignee: BROADCOM CORPORATION, Irvine, CA (US)

(21) Appl. No.: 13/653,330

(22) Filed: Oct. 16, 2012

(51) Int. Cl. H01L 23/495; H01L 23/34; H01L 21/78

(52) U.S. Cl. 257/675; 438/113; 257/E23.051; 257/E21.599

(57) ABSTRACT

Methods, systems, and apparatuses for integrated circuit packages are provided. An integrated circuit package, such as a quad flat no-lead (QFN) package, includes a plurality of peripherally positioned leads, a heat spreader, an integrated circuit die, and an encapsulating material. The peripherally positioned leads are attached to a first surface of the heat spreader, and the die is attached to the first surface of the heat spreader within a ring formed by the leads. The encapsulating material encapsulates the die on the heat spreader, encapsulates bond wires, and fills a space between the leads. A second surface of the heat spreader is exposed from the package. End portions of the leads have surfaces that are flush with a surface of the package opposite the second surface of the heat spreader, and that are used as lands for the package.

### BACKGROUND

1. Technical Field

The present invention relates to integrated circuit packaging technology.

2. Background Art

Integrated circuit (IC) chips or dies from semiconductor wafers are typically interfaced with other circuits using a package that can be attached to a printed circuit board (PCB). One such type of IC die package is a quad flat package (QFP). A QFP is a four sided package that has leads extending from all four sides. The leads are used to interface the QFP with a circuit board when the QFP is attached to the circuit board during a surface mount process.

A type of integrated circuit package that is similar to the QFP is a quad flat no lead (QFN) package. Similarly to a QFP, a QFN package has four sides, but does not have leads that extend outward from the sides of the package. Instead, a bottom surface of the QFN package has contacts/lands that may be referred to as “pins.” The contact pins interface the QFN package with a circuit board when the QFN is attached to the circuit board during a surface mount process.

QFN packages are undergoing a rapid growth in their use in industry due to their advantages, such as small size, thin profile, low weight, and low cost. As products operate at increasingly higher speeds and require increasing amounts of power, products also generate increasing amounts of heat that must be dissipated in ever smaller electronic devices. In current QFN packages, the die may be mounted to a metal heat spreader of the QFN package, and metal heat spreader may be attached to circuit board (by soldering) when the QFN is mounted thereto. However, heat does not efficiently transfer from the die, through the metal heat spreader, into the circuit board. This is because the dielectric material of the circuit board has low thermal conductivity for heat dissipation. In addition, the circuit board is typically small and thin for mobile application devices, such as smart phones, e-readers, and tablet computers. Heat that is generated by a solder-down QFN package can quickly pass into and heat up the circuit board, preventing further power dissipation into the circuit board.

### BRIEF SUMMARY

Methods, systems, and apparatuses are described for die-down integrated circuit packages that include a heat spreader having a first surface to which an integrated circuit die and leads are mounted, the leads extending towards an opposing side of the package from the heat spreader, and the heat spreader having a second surface that is exposed from the package, substantially as shown in and/or described herein in connection with at least one of the figures, as set forth more completely in the claims.

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1 shows a cross-sectional view of an example quad flat no-lead (QFN) package.

FIG. 2 shows a cross-sectional side view of a die-down QFN package mounted to a circuit board, in accordance with an exemplary embodiment.

FIG. 3 shows a cross-sectional side view of a die-down QFN package, in accordance with an exemplary embodiment.

FIG. 4 shows a cross-sectional side view of a die-down QFN package with a heat sink mounted thereto, in accordance with an exemplary embodiment.

FIG. 5A shows a bottom view of the die-down QFN package of FIG. 2, in accordance with an exemplary embodiment.

FIG. 5B shows a bottom view of the die-down QFN package of FIG. 3, in accordance with an exemplary embodiment.

FIG. 6 shows a flowchart providing an example process for spreading heat generated by an IC die in a die-down QFN package, in accordance with an exemplary embodiment.

FIG. 7 shows a flowchart providing a process for constructing a die-down QFN package, in accordance with an exemplary embodiment.

FIG. 8A shows a combined panel in which die-down QFN packages similar to the package of FIG. 2 are being fabricated, in accordance with an exemplary embodiment.

FIG. 8B shows a combined panel in which die-down QFN packages similar to the package of FIG. 3 are being fabricated, in accordance with an exemplary embodiment.

Example embodiments will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### Introduction

The present specification discloses numerous example embodiments. The scope of the present patent application is not limited to the disclosed embodiments, but also encompasses combinations of the disclosed embodiments, as well as modifications to the disclosed embodiments.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

The example embodiments described herein are provided for illustrative purposes, and are not limiting. Although described below with reference to die down QFN packages, the examples described herein may be adapted to other types of lead frame-based integrated circuit packages. Furthermore, additional structural and operational embodiments, including modifications/alterations, will become apparent to persons skilled in the relevant art(s) from the teachings herein.

### Example Embodiments

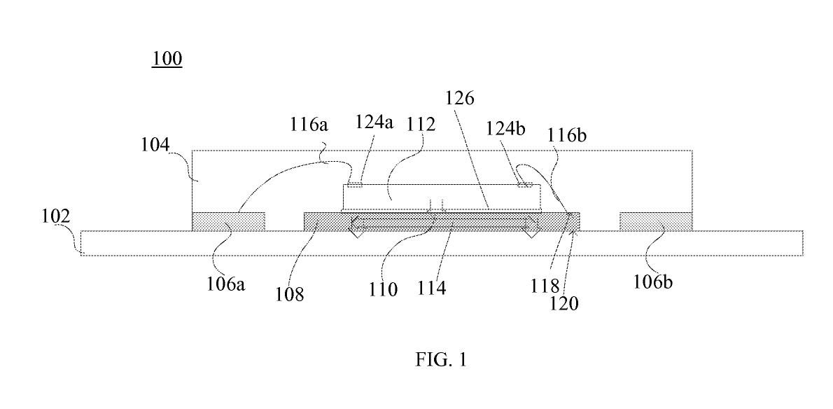

Embodiments relate to lead frame-based integrated circuit packages, such as die-down quad flat no-lead (QFN) packages. For instance, FIG. 1 shows a cross-sectional side view of an example QFN package 100. QFN package 100 includes a heat spreader 108, an integrated circuit die/chip 112, a plurality of peripherally attached leads 106a and 106b, first and second bond wires (also known as “wire bonds”) 116a and 116b, first and second pads 124a and 124b (on an active surface of die 112), and an encapsulating material 104. In FIG. 1, QFN package 100 is shown mounted to a printed circuit board (PCB) 102.

Heat spreader 108 has a first (e.g., top) surface 118 that is opposed to a second (e.g., bottom) surface 120 of heat spreader 108. IC die 112 is attached to first surface 118, and second surface 120 is attached to PCB 102 when package 100 is mounted to PCB 102. Die 112 is an integrated circuit chip/or die that includes a miniature electronic circuit formed of semiconductor devices on an active surface (e.g., top surface in FIG. 1) of die 112. Die 112 may be mounted to heat spreader 108 using an adhesive material 126.

As shown in FIG. 1, a plurality of bond wires are coupled between pads/terminals of die 112 (where signals of die 112 are present) and either leads or first surface 118 of heat spreader 102. For example, first bond wire 116a is connected between pad 124a of die 112 and lead 106a, and second bond wire 116b is connected between pad 124b and first surface 118 of heat spreader 102. Any number of bond wires may be present, depending on the number of signals at corresponding pads of die 112 to be coupled to leads and/or first surface 118 of the heat spreader 102.

As shown in FIG. 1, leads 106a and 106b serve as lands/contacts for mounting QFN package 100 to PCB 102 during a surface mount process. Leads 106a and 106b may be attached to corresponding lands on PCB 102 by soldering or other adhesive. Although not visible in FIG. 1 a ring of leads may surround die 112 in QFN package 100 that are each coupled to a corresponding bond wire, and attached to a corresponding land of PCB 102. Heat spreader surfaces 118 and 120 have surface areas that are smaller than an area within a boundary defined by the inner edges of leads 106a and 106b (i.e., surfaces 118 and 120 do not extend out to leads 106a and 106b) and any further leads (not shown) that may surround die 112.

As further shown in FIG. 1, encapsulating material 104 covers die 112 and bond wires 116a and 116b on leads 106a and 106b. Encapsulating material 104 protects die 112 and bond wires 116a and 116b from environmental hazards.

QFN packages, such as QFN package 100, are undergoing rapid growth in industry due to their many benefits, such as small size, thin profile, low weight, and low cost. As products operate at increasingly higher speeds and require increasing amounts of power, a corresponding increase in the ability to thermally cool QFN packages is needed. In QFN package 100, when power is applied to die 112, die heat is generated, which raises a temperature of die 112. However, such die heat does not easily pass from die 112 through encapsulating material 104. Instead, as shown in FIG. 1, a die heat 110 (indicated by arrows in FIG. 1) flows from die 112 through adhesive material 126 to heat spreader 108. The heat spreads within heat spreader 108 as heat spreader heat 114. Some of heat spreader heat 114 transfers into PCB 102, heating up PCB 102 and its related electronic elements.

However, heat dissipation is limited in PCB 102 due to the materials of PCB 102. For instance, circuit boards such as PCB 102 tend to be formed of dielectric material layers (not electrically conductive) alternated with electrically conductive metal layers (that include routing, power and ground planes, etc.). Such dielectric material layers contain materials such as FR4 that are not efficient conductors of heat (have low thermal conductivity). As such, heat does not efficiently transfer from heat spreader 108 into PCB 102, and therefore the temperature of die 112 may not be reduced sufficiently. Excess heat in die 102 will elevate the die temperature, which may cause malfunction of die 112, cracks in die 112, and/or other problems with QFN package 100. The metal layer count in PCB 102 may be increased to aid in heat dissipation, but this comes with an added cost to PCB 102 in terms of materials and additional process steps. For relatively high power dissipation (e.g., in the range of 5 W to 20 W or higher), QFN package 100 and other types of exposed pad die-down lead frame packages are inadequate.

Furthermore, in some cases, QFN package 100 may have additional rings of leads that surround die 112 in QFN package 100 in concentric rectangles, with each lead coupled to a corresponding bond wire, and attached to a corresponding land of PCB 102. Such additional rings of leads are useful in packages that have relatively high numbers of die signals. However, increasingly longer bond wires are used to connect between pads of die 112 and the leads of the outer rings of leads. These longer bond wires cause higher RLC (resistance-inductance-capacitance) values, and therefore lead to lower signal quality. Furthermore, such longer bond wires suffer from an increased risk of wire sagging and wire swiping during a mold encapsulation process that applies encapsulating material 104. This can cause undesired shorting together of bond wires, as well as bond wires being exposed on the top of encapsulating material 104.

Embodiments are described herein that overcome these weaknesses in QFN packages. For instance, embodiments are described for integrated circuit packages with enhanced mechanical and thermal characteristics relative to QFN package 100. In an embodiment, an integrated circuit package includes a heat spreader having a first surface to which one or more integrated circuit dies and a plurality of leads are mounted. The leads extend towards an opposing side of the package from the heat spreader, and the heat spreader has a second surface that is exposed from the package. In this manner, heat may be spread from the die to the heat spreader into the air, and optionally into one or more heat sinks attached to the heat spreader. Methods and apparatuses for such integrated circuit packages, and processes for assembling and cooling the same, are described herein.

For instance, in first aspect, an integrated circuit (IC) package includes a heat spreader, a plurality of peripherally positioned leads, an electrically insulating adhesive layer, an IC die, a plurality of wire bonds, and an encapsulating material. The IC die is attached to the heat-spreader, positioned within a ring formed by the peripheral leads. The peripherally positioned leads are attached to the heat spreader by the electrically insulating adhesive layer. The encapsulating material encapsulates the die, bond wires connected between the die and the leads, and at least a portion of the leads.

In another aspect, a method for cooling an IC die in an IC package is provided. Power is applied to the IC die, causing the IC die to generate heat. An electrical signal is generated in the IC die that is conducted from a first pad on an active surface of the IC die through a wire bond to an electrically conductive lead. The lead has a first end portion (also referred to as a “bond finger”) attached to the first surface of the heat spreader by an electrically insulating adhesive layer and a second end portion configured to be mounted to a printed circuit board (PCB). The IC die is mounted to a heat spreader in the IC package. The heat spreader has a first surface and a second surface (the IC die is attached to the first surface). Heat from the heat spreader is inhibited from being transferred to the lead by the electrically insulating adhesive layer. Furthermore, heat from the IC die is inhibited from being transferred directly to the surface of the PCB by an encapsulating material between the IC die and the PCB. The encapsulating material encapsulates the IC die, the wire bond, and a portion of the lead. However, heat is spread from the IC die to the heat spreader (through an adhesive material), and the heat is radiated into the environment from the heat spreader (which is exposed to the environment at least at its second surface, and/or has a heat sink mounted to its second surface).

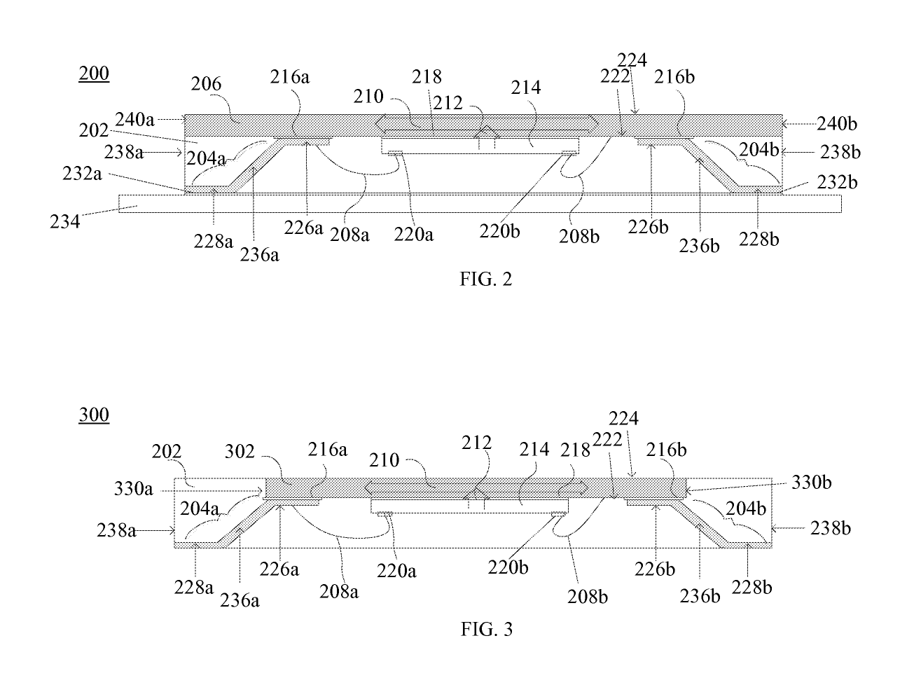

FIG. 2 shows a cross sectional side view of a die down QFN package 200 mounted to a circuit board, according to an example embodiment. As shown in FIG. 2, die down QFN package 200 includes a heat spreader 206, an integrated circuit die/chip 214, a plurality of peripherally attached leads 204a and 204b, first and second bond wires (also known as “wire bonds”) 208a and 208b, first and second pads 220a and 220b on an active surface of die 214, and an encapsulating material 202. Furthermore, package 200 is shown in FIG. 2 as mounted on a circuit board 234. Circuit board 234 may be any suitable type of circuit board, including a printed circuit board (PCB), etc. Die down QFN package 200 is described as follows.

As shown in FIG. 2, heat spreader 206 has a first (e.g., bottom) surface 222 that is opposed to a second (e.g., top) surface 224. Although two leads 204a and 204b are shown in FIG. 2, any number of leads may be present. Heat spreader 206 has an area such that perimeter edges 240a and 240b of heat spreader 206 are co-planar with the corresponding perimeter edges 238a and 238b of package 200. First lead 204a has a first end portion 226a, a down set portion 236a, and a second end portion 228a, and second lead 204b has a first end portion 226b, a down set portion 236b, and a second end portion 228b. First and second end portions 226a and 226b may also be referred to as “bond fingers.” A bond finger is a portion of a lead to which a wire bond connects. First end portions 226a and 226b are attached to the first surface 222 of the heat spreader 206 (at opposed ends of first surface 222) by electrically insulating adhesive layers 216a and 216b, respectively. Down set portions 236a and 236b of leads 204a and 204b connect between the respective first and second ends of leads 204a and 204b, providing an electrically conductive path for signals between each first end portion and respective second end portion. As shown in FIG. 2, bottom surfaces of second edge portions 228a and 228b of leads 204a and 204b are attached to respective land pads of circuit board 234 by solder layers 232a and 232b, respectively. Second end portions 228a and 228b of leads 204a and 204b serve as lands/contacts for mounting die down QFN package 200 to a circuit board 234 during a surface mount process. Insulating adhesive layers 216a and 216b may be any type of adhesive material that is electrically insulating, such as a dielectric tape, film, an electrically non-conductive epoxy, or other electrically non-conductive adhesive.

IC die 214 is mounted to first surface 222 of heat spreader 206 by an adhesive material 218. Adhesive material 218 may be any type of suitable adhesive material, including an epoxy, solder, glue, or other adhesive, which may be electrically conductive (e.g., a silver particle filled epoxy) or non-electrically conductive. Pads 220a and 220b are die pads or terminals (e.g., aluminum pads, etc.) where signals of die 214 are accessible. Any number of such pads may be present on the active surface of die 214. Bond wire 208a is attached between pad 220a and lead 204a at first end portion 226a, and bond wire 208b is attached between pad 220b and first surface 222 of heat spreader 206. As such, heat spreader 206 may be used as a ground or power plane for package 200 (e.g., heat spreader 206 may be coupled to an electrical ground or power signal of die 214 by bond wire 208b). Any number of bond wires may be present to couple pads on the active surface of die 214 to corresponding leads or to first surface 222.

Bond wires 208a and 208b may be wires formed of any suitable electrically conductive material, including a metal such as gold, silver, copper, aluminum, nickel, tin, other metal, or combination of metals/alloy. Bond wires 208a and 208b (as well as further bond wires) may be attached according to wire bonding techniques and mechanisms well known to persons skilled in the relevant art(s). It is noted that adhesive layers 216a and 216b may provide support for leads 204a and 204b (e.g., for a lead frame) during the wire bonding process.

Leads 204a and 204b (and any further leads that are present) may be made of an electrically conductive material, including a metal such as copper, aluminum, tin, nickel, gold, silver, or other metal, or a combination of metals/alloy, such as a solder, etc. Leads 204a and 204b may have been separated from a lead frame (also referred to as a “leadframe”), or may be formed in another manner. The surfaces of leads 204a and 204b (and any further leads that are present), and/or first surface 222 and second surface 224 of heat spreader 206 may optionally be coated with an electrically conductive material and/or be otherwise surface treated. Electrically conductive coatings may be any suitable electrically conductive material, including a metal such as copper, aluminum, tin, nickel, gold, silver, or other metal, or a combination of metals/alloy, such as a solder, etc. Electrically conductive coatings may be formed on a surface of leads 204a and 204b (and any further leads that are present), and/or surfaces 222 and 224 in any manner, including by a plating technique (e.g., electroplating), a printing technique, photolithography, or other technique.

As shown in FIG. 2, encapsulating material 202 encapsulates bond wires 208a and 208b, die 214 (on first surface 222), first surface 222, and leads 204a and 204b (other than a bottom surface of each of second end portions 228a and 228b). In FIG. 2, edges of encapsulating material 202 are flush/even with edges 238a and 238b of package 200 (e.g., due to saw singulation or other technique). Encapsulating material 202 may be any suitable type of encapsulating material, including an epoxy, a ceramic material, a plastic material, a mold compound, etc. Encapsulating material 202 may be applied in a variety of ways, including by a saw singulation technique, injection into a mold, etc.

As such, in package 200, the active surface of die 214 is facing downwards towards circuit board 234 to which package 200 is mounted (facing towards the exposed surfaces of leads 204a and 204b used as lands). Thus, package 200 is considered a die down package. Package 200 has improved thermal performance (relative to package 100 of FIG. 1) due to an integrated heat spreader (heat spreader 206) that improves heat dissipation through the package top. Furthermore, a reduction in die-to-package bond wire lengths are enabled, as bond wires are coupled to leads (e.g., lead frame bond fingers) rather than to package I/O leads. First end portions 226a and 226b (e.g., bond fingers) of leads 204a and 204b can be positioned very close to die 214. This reduces signal RLC through a reduction of bond wire length, reducing a loop inductance. Still further, this reduces wire swiping (shorting) and exposing bond wires during mold encapsulation for higher I/O pin-count packages. A device (die 214) junction-to-top case thermal resistance (Theta-JC) is reduced to the die-to-heat spreader attachment at the package top. A device junction-to-board thermal resistance (Theta-JB) is reduced due to heat spreading by heat spreader 206, which is substantially larger in size than heat spreader 108 (FIG. 1) for a same sized package. Furthermore, a mechanical support is provided by heat spreader 206 for a large size heat sink attachment to package 200, which increases area for heat dissipation.

FIG. 3 shows a cross-sectional side view of a die-down QFN package 300, in accordance with another exemplary embodiment. For purposes of illustration, package 300 is not shown mounted to a circuit board. Package 300 in FIG. 3 is similar to package 200 of FIG. 2, with differences described as follows. For instance, as shown in FIG. 3, package 300 includes a heat spreader 302 instead of heat spreader 206 of FIG. 2. Heat spreader 302 is generally similar to heat spreader 206, except that heat spreader 302 has a smaller area than heat spreader 206 (for a same sized package) such that perimeter edges 330a and 330b of heat spreader 302 do not extend to the corresponding perimeter edges 238a and 238b of package 300. Instead, perimeter edges 330a and 330b are covered by encapsulating material 202. In package 300, any one or more of the perimeter edges of heat spreader 302 may not extend to the corresponding perimeter edge(s) of package 300. However, surface 222 of heat spreader 302 has an area that overlaps with first portions 226a and 226b of leads 204a and 204b (and further leads that may be present). As such, first portions 226a and 226b of leads 204a and 204b may be attached to surface 222 of heat spreader 302 in a similar manner as shown in FIG. 2 for package 200.

Package 300 of FIG. 3 may be mounted to a circuit board in a similar manner as package 200 of FIG. 2. In embodiments, second surfaces 224 of heat spreaders 206 (FIGS. 2) and 302 (FIG. 3) may remain exposed to the environment as shown in FIGS. 2 and 3. In another embodiment, a heat sink or other device may be mounted to heat spreaders 206 and/or 302 to increase thermal dissipation.

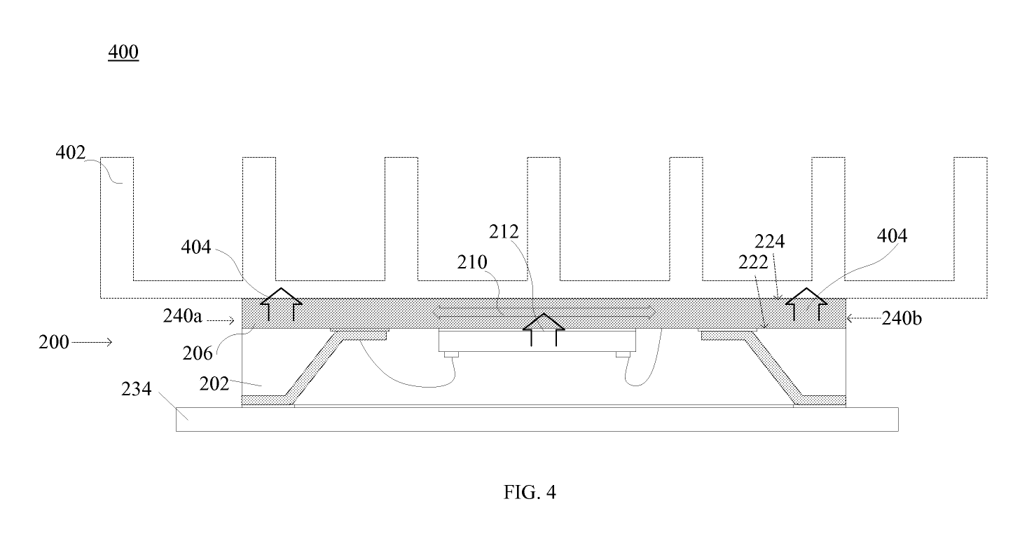

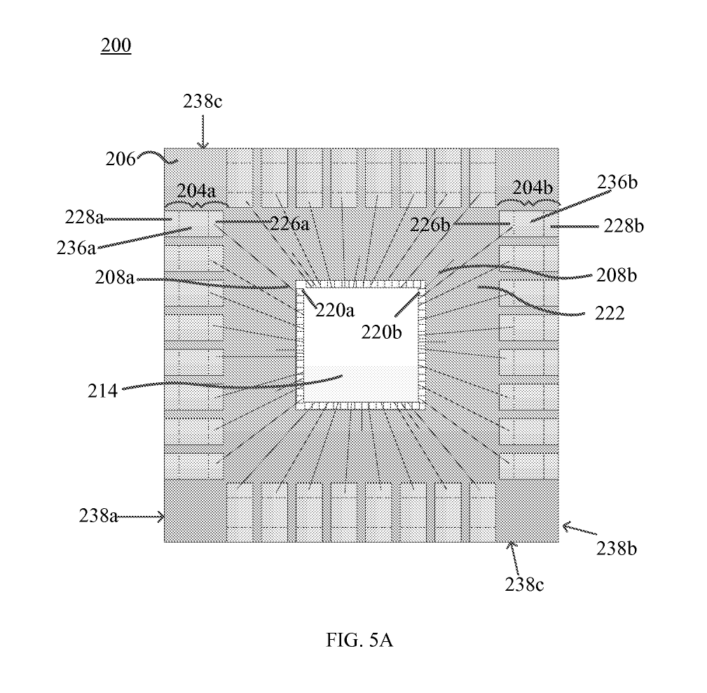

For instance, FIG. 4 shows a cross-sectional side view of a die-down QFN package 400 that includes package 200 of FIG. 2 with a heat sink 402 mounted thereto, in accordance with an exemplary embodiment. As shown in FIG. 4, heat sink 402 is attached to second surface 224 of heat spreader 206. Heat 210 of heat spreader 206 transfers from heat spreader 206 into heat sink 402 as heat 404 (indicated by arrows).

Heat sink 402 can have any shape, including as a rectangular body, or a body that has one or more fins or flanges extending therefrom (as shown in FIG. 4) to enhance thermal transfer into the environment. Heat sink 402 may be made from any suitable material, including a metal such as copper, aluminum, tin, nickel, gold, silver, or other metal, or combination of metals/alloy, or any other suitable heat sink material, as would be known to persons skilled in the relevant art(s).

In a further embodiment, second surfaces 224 of heat spreader 206 or 302 may be attached to the chassis of an electronic device, or to other heat dissipating structure. The chassis can effectively serve as a heat sink. Second surface 224 may be attached to a heat sink, a chassis, or other structure in any manner, including by a thermally conductive adhesive mentioned elsewhere herein or otherwise known.

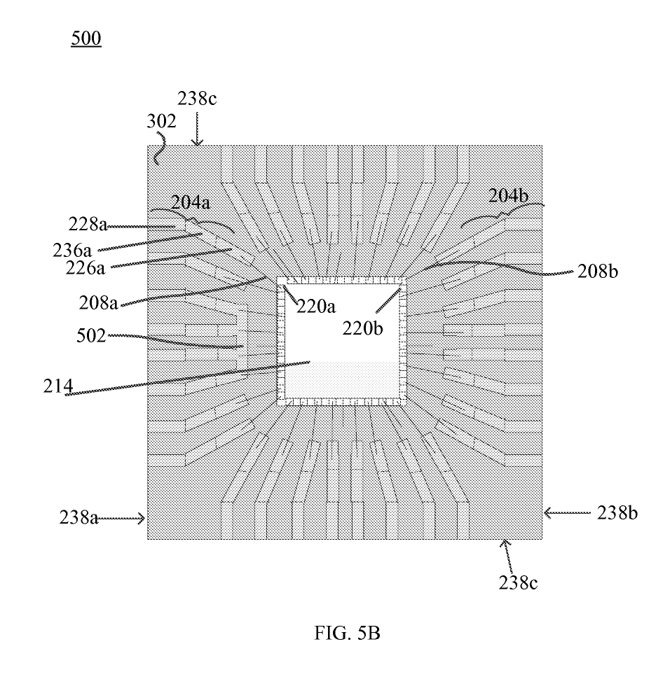

Note that leads may be distributed in a package in various ways, in embodiments. For instance, FIG. 5A shows a bottom view of package 200 of FIG. 2, in accordance with an exemplary embodiment. As shown in FIG. 5A and described above, package 200 includes integrated circuit die/chip 214, leads 204a and 204b, bond wires 208a and 208b, die pads 220a and 220b, and heat spreader 206. Encapsulating material 202 is not shown in FIG. 5A for ease of illustration.

As shown in FIG. 5A, leads 204a, 204b, and a plurality of further leads are arranged in a rectangular ring around die 214, along the four perimeter edges 238a-238d of package 200. The leads can have first end portions 226a and 226b (e.g., bond fingers), down-set portions 236a and 236b, and second end portions 228a and 228b, as illustrated by the dotted lines on the leads of FIG. 5A. Eight leads are shown along each of perimeter edges 238a-238d, although in other embodiments, other numbers of leads may be present. Each lead has a corresponding first end of a bond wire coupled to a first end portion (e.g., bond finger), a down set portion, and a second end coupled to a die pad of die 214. Furthermore, a plurality of bond wires are shown that each have a first end coupled to a die pad of die 214 and a second end coupled to first surface 222 of heat spreader 206.

It is noted that leads 204a, 204b, and further leads that are present may be generally rectangular, as shown in FIG. 5A, or may have other shapes. For instance, leads can have shapes that are configured to extend closer to a package die so that bond wires between the die and leads can have relatively shorter lengths. Such leads may be angled, curved, or have one or more bends, etc.

For instance, FIG. 5B shows a bottom view of package 200, in accordance with another exemplary embodiment. Package 500 in FIG. 5B is similar to package 200 of FIG. 5A, with differences described as follows. For instance, as shown in package 500 of FIG. 5B, the package leads, such as leads 204a and 204b, are non-rectangular in shape. Instead, the down set and bond finger portions of the leads of package 500 are bent towards die 214 to so that the first end portions (bond fingers) are closer to die 214, thereby reducing the distance that bond wires have to bridge between the die pads and first end portions. The leads of package 500 located the furthest distance from IC 214 (the leads closest to the corners of package 500), such as leads 204a and 204b, have the greatest angles bending towards die 214, and may be longer than the leads located on the center of edges. By bending one or more leads, and optionally lengthening the furthest out leads, the length of bond wires can be shortened, reducing RLC values and preventing loss of signal quality in the bond wires. The leads can further be arranged in other manners such that their first end portions form diamond, circular, or elliptical shape rings, to enable the leads to extend more closely to the package die.

In an embodiment, adjacent bond fingers of the die-down QFN design may also be connected to one another, as shown in FIG. 5B. For instance, package 500 includes a plurality of fused inner fingers 502. Fused inner fingers 502 includes the first end portions of four leads that are fused together (by electrically conductive traces) to be electrically connected. One or more wire bonds may be connected between die pads of die 214 and fused inner fingers 502 to electrically connect the corresponding electrical signal between those die pads and the leads fused by fused inner fingers 502. For instance, a power supply signal (0.7V, 1.5V, 2.2V, etc.), a ground signal, or other signal may be coupled to fused inner fingers 502 so that all of the fused leads carry the signal. This feature is not compatible with package 100 shown in FIG. 1.

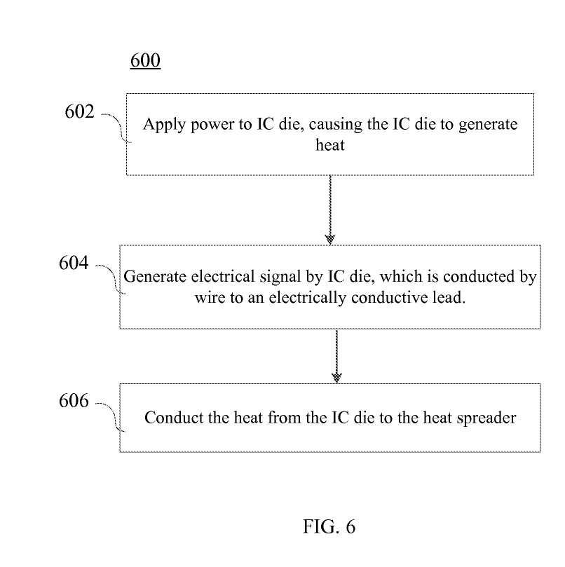

As described above, package embodiments dissipate heat generated by the package die in an efficient manner. For instance, FIG. 6 shows a flowchart 600 providing an example process for spreading heat generated by an IC die in a die-down QFN package, in accordance with an exemplary embodiment. For instance, flowchart 600 may be performed by package 200 of FIGS. 2, 4, and 5A, package 500 of FIG. 5B, or package 300 of FIG. 3. The steps of flowchart 600 may be performed in various orders, as would be understood by persons skilled in the relevant art(s) from the teachings herein. For purposes of illustration, flowchart 600 is described as follows with reference to FIG. 2.

Flowchart 600 beings with step 602. In step 602, power is applied to an IC die, causing heat to be generated in the IC die. For example, referring to FIG. 2, power may be applied to IC die 214 by powering up a device in which die 214 is included. Die 214 begins to operate once power is applied, causing die 214 to generate heat due to circuit function therein.

In step 604, an electrical signal is generated by the IC die, which is conducted by a bond wire to an electrically conductive lead. For instance, referring to FIG. 2, an electrical signal may be generated by die 214, which is conducted from die pad 220a by bond wire 208a to first end portion 226a of lead 204a. Lead 204a is attached to heat spreader 206 with electrically insulating adhesive layer 216a at first end portion 226a, and is connected to circuit board 234 on second end portion 228a.

In step 606, heat is conducted from the IC die to the heat spreader. As shown in FIG. 2, die heat 212 is produced within the die 214. Die heat 212 conducts across adhesive material 218 into heat spreader 206. In embodiments, adhesive material 218 may be configured to have high thermal conductivity and/or may be thin enough to not significantly inhibit transfer of heat. Die heat 212 transfers to heat spreader 206 as heat 210 inside heat spreader 206, which spreads within heat spreader 206 to the perimeter edges 240a and 240b of heat spreader 206 (which are exposed to the environment from package 200). In this manner, heat spreader 206 aids in significantly cooling die 214. In some embodiments, heat spreader 206 may have a higher thermal conductivity than that of die 214. For example, a copper version of heat spreader 206 may have a thermal conductivity of ˜400 W/m·K and die 214 may have a thermal conductivity of ˜150 W/m·K. As such, the thermal conductivity of heat spreader 206 is much greater than the thermal conductivity of die 214 (nearly 3 times greater). In some embodiments, no organic compounds are present on the surfaces of die 214, heat spreader 206, and/or in adhesive material 218 to maximize thermal conductivity and heat transfer.

It is noted that leads 204a and 204b can provide some transfer of heat from heat spreader 206 (or heat spreader 304) to circuit board 234, although this transfer of heat is inhibited somewhat by insulating adhesive layers 216a and 216b. For instance, as shown in FIG. 2, electrically insulating adhesive layers 216a and 216b provide additional thermal barriers and inhibit (e.g., at least reduce) heat 210 of heat spreader 302 from conducting to leads 204a and 204b. Insulating adhesive layers 216a and 216b typically do not have significant thermal conductivity. As such, leads 204a and 204b aid less in cooling die 214 than heat spreaders 206 and 302.

Furthermore, in FIG. 2, the transfer of heat from die 214 directly to the surface of circuit board 234 can occur through encapsulating material 202, although this heat transfer is inhibited by encapsulating material 202 and is less efficient. Encapsulating material 202, which typically does not have significant thermal conductivity, can provide a thermal barrier between die 214 and circuit board 234. For instance, in some embodiments, encapsulating material 202 may have a lower thermal conductivity than the die. For example, encapsulating material 202 may have a thermal conductivity of 0.5-1.5 W/m·K and die 214 may have a thermal conductivity of 150 W/m·K. As such, encapsulating material 202 does not aid significantly in cooling die 214

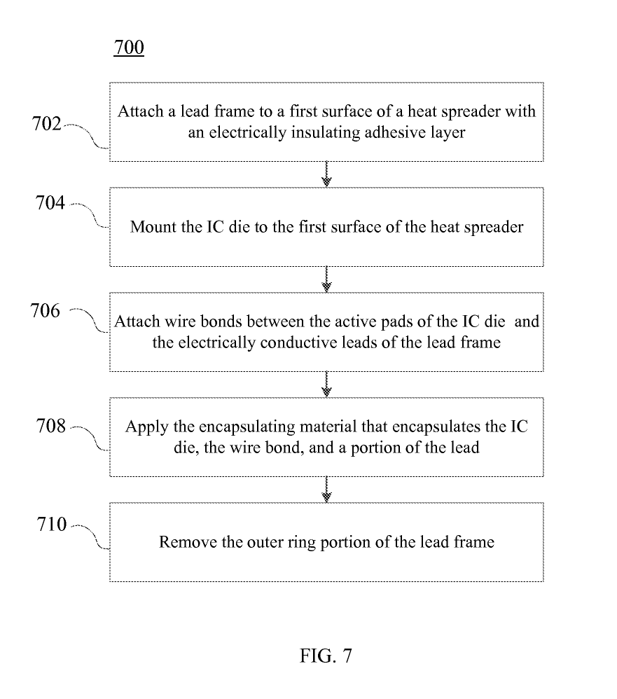

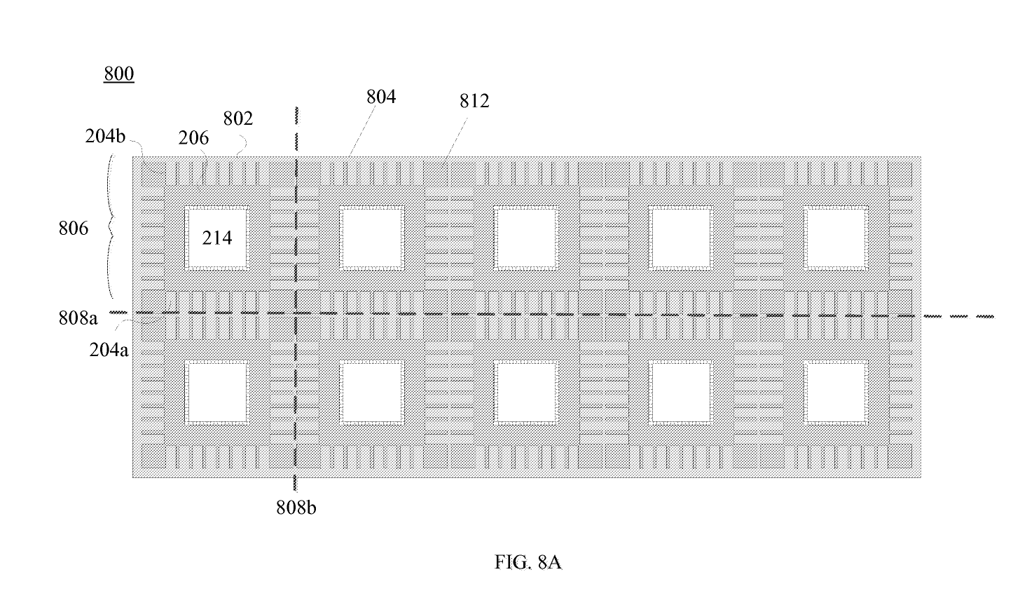

Package embodiments described herein may be fabricated in various ways in embodiments. For instance, FIG. 7 shows a flowchart 700 providing a process for constructing a die-down QFN package, in accordance with an exemplary embodiment. For instance, flowchart 700 may be used to assemble package 200 of FIGS. 2, 4, and 5A, package 500 of FIG. 5B, and package 300 of FIG. 3. The steps of flowchart 700 may be performed in various orders, as would be understood by persons skilled in the relevant art(s) from the teachings herein. For purposes of illustration, flowchart 700 is described as follows with reference to FIG. 2.

Flowchart 700 beings with step 702. In step 702, a lead frame is attached to a surface of a heat spreader by an electrically insulating adhesive layer. For example, FIG. 2 shows individual leads 204a and 204b attached to first surface 222 of heat spreader 206. In an embodiment, leads 204a and 204b (and further leads) may be attached to heat spreader 206 individually, or as part of a single unit referred to as a “lead frame.” A lead frame includes a ring (e.g., a rectangular ring) of leads extending inwardly from a surrounding ring-shaped frame. After assembling a package, the surrounding ring-shaped frame may be removed (e.g., during package singulation from a panel of lead frames) to separate the leads from each other. The electrically insulating adhesive material (e.g., adhesive layers 216a and 216b) may be applied to the lead frame, and subsequently the lead frame may be applied to the package heat spreader, or the adhesive material may be applied to the package heat spreader, and the lead frame may be applied to the adhesive material on the package heat spreader.

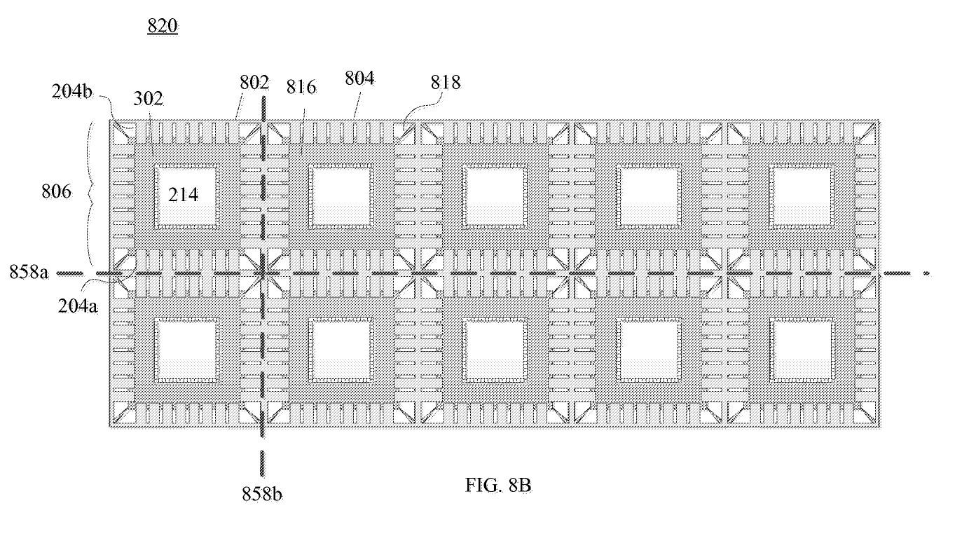

It is noted that in embodiments, packages, such as packages 200, 300, and 500, may be assembled according to flowchart 700 individually or in parallel. For instance, step 702 of flowchart 700 may be performed by attaching a plurality of lead frames to a plurality of heat spreaders simultaneously (e.g., in panel form). For example, FIG. 8A shows a combined panel 800 in which a plurality of packages (similar to package 200 of FIG. 2) is being fabricated in parallel, in accordance with an exemplary embodiment. FIG. 8A is described as follows.

As shown in FIG. 8A, combined panel 800 includes a lead frame panel 804 and a heat spreader panel 812. Lead frame panel 804 and heat spreader panel 812 are fabricated separately from each other (e.g., each fabricated from a sheet or panel of electrically conductive material). Lead frame panel 804 is attached to heat spreader panel 812 (e.g., by a continuous or multi-section electrically insulating material layer, such as electrically insulating adhesive layers 216a and 216b described above). Lead frame panel 804 includes a plurality of lead frames (ten lead frames in this example) connected together in an array (a five by two array in this this example), including a first lead frame 806. Lead frame 806 includes an outer ring-shaped frame portion 802 and a plurality of leads (e.g., leads 204a and 204b) that extend inward from outer ring-shaped frame portion 802. When outer frame portion 802 is removed from lead frame 806 (e.g., by making cuts in combined panel 800 represented by dotted lines 808a and 808b), the connected leads become mechanically and electrically isolated from each other to form individual leads (e.g., leads 204a and 204b) in their respective packages.

Heat spreader panel 812 is shown underneath and visible through lead frame panel 804 in FIG. 8A, and includes a plurality of heat spreaders (ten heat spreaders in this example) connected together in an array, including a heat spreader 206. The heat spreaders of heat spreader panel 812 are separated from each other when combined panel 800 is separated, as described above.

Thus, in an embodiment, as shown in FIG. 8A, heat spreaders (e.g., heat spreaders 206) are fabricated in a heat spreader panel separately from a lead frame panel, which allows each individual heat spreader to overlap with a corresponding lead frame when combined panel 800 is formed, and to optionally be a different thickness than the lead frame. For instance, the area of heat spreader 206 in heat spreader panel 812 may be sized to partially overlap the leads of lead frame 806, or to fully overlap the leads of lead frame 806 to have edges that are co-planar with the edges of the resulting package.

For example, in the embodiment of FIG. 3, heat spreader 302 covers first end portions 226a and 226b of leads 204a and 204b, but does not overlap any further portion of leads 204a and 204b. In the embodiment of FIG. 2, heat spreader 206 fully overlaps leads 204a and 204b, and edges 240a and 240b of heat spreader 206 are coplanar with peripheral edges 238a and 238b of package 200. Increasing a ratio of the surface area of a heat spreader to the surface area of the die increases an ability of the heat spreader to dissipate heat from the die. In some embodiments, the thickness of a heat spreader (the distance between surfaces 222 and 224) may be greater than the thickness of leads 204a and 204b so that the heat spreader has greater mass and larger cross-section areas, enabling greater heat sinking and spreading capability without significantly increasing an overall package thickness. For example, FIGS. 2 and 3 each depict heat spreaders (heat spreaders 206 and 302, respectively) that have thicknesses that are greater than the thickness of leads 204a and 204b.

Lead frame 806 may be formed separately or in lead frame panel 804 according to any suitable process, including by a conventional lead frame fabrication process, or by a proprietary process. For example, in embodiments, lead frame 806 (and optionally lead frame panel 804) may be formed by receiving a foil or sheet of an electrically conductive material, and etching, cutting, or otherwise forming leads 208a and 208b and/or other features in the foil or sheet. Such etching or cutting may be performed using chemical etching, photolithography, laser etching, mechanical etching, a punching mechanism, or other suitable process. Alternatively, lead frame 806 (and optionally lead frame panel 804) may be formed by injecting an electrically conductive material into a mold chamber. Lead frame 806 (and lead frame panel 804) may be made of any suitable electrically conductive material, including a metal such as copper, aluminum, tin, nickel, gold, silver, or other metal, or combination of metals/alloy, or any other suitable electrically conductive material, as would be known to persons skilled in the relevant art(s).

Similarly, heat spreader 206 may be formed separately or in heat spreader panel 812 according to any suitable process, including by a conventional lead frame fabrication process, or by a proprietary process. For example, in embodiments, heat spreader 206 (and optionally heat spreader panel 812) may be formed from a foil or sheet of an electrically conductive material, and etching, cutting, or otherwise features in the foil or sheet as needed. Such etching or cutting may be performed using chemical etching, photolithography, laser etching, mechanical etching, a punching mechanism, or other suitable process. Alternatively, heat spreader 206 (and optionally heat spreader panel 812) may be formed by injecting an electrically conductive material into a mold chamber. Heat spreader 206 (and optionally heat spreader panel 812) may be made of any suitable electrically conductive material, including a metal such as copper, aluminum, tin, nickel, gold, silver, or other metal, or combination of metals/alloy, or any other suitable electrically conductive material, as would be known to persons skilled in the relevant art(s).

Thus, FIG. 8A shows packages similar to package 200 of FIG. 2 being formed in panel form in parallel. In another embodiment, packages similar to package 300 of FIG. 3 may be formed in panels in parallel. For instance, FIG. 8B shows a combined panel 820 in which packages similar to package 300 of FIG. 3 are being fabricated, in accordance with an exemplary embodiment. FIG. 8B is described as follows.

As shown in FIG. 8B, combined panel 820 includes lead frame panel 804 and a heat spreader panel 816. Lead frame panel 804 and heat spreader panel 816 are fabricated separately from each other (e.g., each fabricated from a sheet or panel of electrically conductive material). Lead frame panel 804 is attached to heat spreader panel 816 (e.g., by a continuous or multi-section electrically insulating material layer, such as electrically insulating adhesive layers 216a and 216b described above). Similarly to the description with respect to FIG. 8A, lead frame panel 804 of FIG. 8B includes a plurality of lead frames (ten lead frames in this example) connected together in an array (a five by two array in this this example), including a first lead frame 806. Lead frame 806 includes an outer ring-shaped frame portion 802 and a plurality of leads (e.g., leads 204a and 204b) that extend inward from outer ring-shaped frame portion 802. When outer frame portion 802 is removed from lead frame 806 (e.g., by making cuts in combined panel 800 represented by dotted lines 858a and 858b), the connected leads become mechanically and electrically isolated from each other to form individual leads (e.g., leads 204a and 204b) in their respective packages.

Heat spreader panel 816 is shown underneath and visible through lead frame panel 804, and includes a plurality of heat spreaders (ten heat spreaders in this example) connected together in an array, including a heat spreader 302. In heat spreader panel 816, the connected heat spreaders do not have areas large enough that the edges of heat spreaders connect, but instead there are gaps or spaces between the heat spreaders. As such, in an embodiment, the heat spreaders in heat spreader panel 816 are interconnected by corner located tie bars 818. In the embodiment of FIG. 8B, a tie bar 818 is connected to each corner of a heat spreader, and extends outward to be interconnected with other tie bars connected to other heat spreaders, to form a lattice that supports the heat spreaders. The heat spreaders of heat spreader panel 816 are separated from each other when combined panel 820 is separated, as described elsewhere herein. During this singulation process, the tie bars 818 are disconnected from each other, leaving each tie bar 818 in its respective package as a disconnected tab extending from a corner of the heat spreader. It is noted that in other embodiments, heat spreaders similar to heat spreader 302 may be interconnected in a heat spreader panel in other ways. Furthermore, in embodiments, any number of tie bars may be present to connect each heat spreader into a heat spreader panel, and the tie bars may be located at corners and/or along the edges of heat spreaders at any location(s).

As shown in FIG. 8B, the heat spreaders of heat spreader panel 816, such as heat spreader 302 of package 300 of FIG. 3, have areas large enough to extend beyond the edges of die 214 and beyond the inner perimeter of the individual lead frames of lead frame panel 804, such as lead frame 806. As such, each heat spreader overlaps the first end portion of the leads of the corresponding lead frame.

Heat spreader 302 may be formed separately or in heat spreader panel 816 according to any suitable process, including by a conventional lead frame fabrication process, or by a proprietary process. For example, in embodiments, heat spreader 302 (and optionally heat spreader panel 816) may be formed from a foil or sheet of an electrically conductive material, and etching, cutting, or otherwise features in the foil or sheet as needed. Such etching or cutting may be performed using chemical etching, photolithography, laser etching, mechanical etching, a punching mechanism, or other suitable process. Alternatively, heat spreader 302 (and optionally heat spreader panel 816) may be formed by injecting an electrically conductive material into a mold chamber. Heat spreader 302 (and optionally heat spreader panel 816) may be made of any suitable electrically conductive material, including a metal such as copper, aluminum, tin, nickel, gold, silver, or other metal, or combination of metals/alloy, or any other suitable electrically conductive material, as would be known to persons skilled in the relevant art(s).

Combined panel 820 may be separated into individual packages containing a heat spreader 302 and a lead frame 806 by making cuts 858a and 858b represented by the dotted lines in FIG. 8B prior to performing further steps of flowchart 700, or at any point during flowchart 700 of FIG. 7 (e.g., during step 710).

Referring back to flowchart 700 in FIG. 7, in step 704, the IC die is mounted to the first surface of the heat spreader. For example, in the embodiment of FIG. 2, die 214 may be attached to heat spreader 206. Die 214 may be attached to heat spreader 206 or 302 in any manner, such as by adhesive material 218 shown in FIGS. 2 and 3 and described above. Die 214 may be placed on heat spreader 206 or 302 using a pick-and-place machine, or any other suitable mechanism otherwise known to persons skilled in the relevant art(s). Die 214 may be mounted to any portion of heat spreader 206 or 302, including a central location (e.g., the center) or an off center location. Furthermore, in an embodiment, multiple dies 214 may be mounted to a single heat spreader. As described above, dies may be attached to a panel of heat spreaders. For instance, as shown in each of FIGS. 8A and 8B, a plurality of dies is attached to a heat spreader panel of a combined panel.

In step 706, at least one wire bond is attached between the integrated circuit die and at least one lead of the plurality of leads. For example, as shown in FIG. 2, bond wire 208a may be attached between pad 220a of die 214 and lead 204a. Bond wire 208a may be attached in any manner, including by a conventional wire bonding machine, or by other technique mentioned elsewhere herein or otherwise known, as would be known to persons skilled in the relevant art(s). Bond wire 208a may be made of any suitable electrically conductive material, including a metal such as copper, aluminum, tin, nickel, gold, silver, or other metal, or combination of metals/alloy, or any other suitable electrically conductive material, as would be known to persons skilled in the relevant art(s). Step 706 may be performed for an individual package or for multiple packages being formed in a combined panel.

In step 708, an encapsulating material is applied to encapsulate the integrated circuit die, wire bonds, and at least a portion of the lead. For example, as shown in FIG. 2, encapsulating material 202 may be applied to cover die 114 and bond wires 208a and 208b, and to fill in regions between leads 204a and 204b. In another embodiment, as shown in FIG. 3, encapsulating material 202 may be applied to cover the perimeter edges of heat spreader 302. In embodiments, encapsulating material 202 may cover no perimeter edges, or any one or more perimeter edges, including all perimeter edges, of a heat spreader. Encapsulating material 202 may be applied in any manner, including by injection into a mold, or by other technique mentioned elsewhere herein or otherwise known, as would be known to persons skilled in the relevant art(s). Encapsulating material 202 may be applied to encapsulate an individual package, or may be applied to a combined panel (e.g., combined panels 800 and 820) to encapsulate a plurality of packages being formed.

In step 710, the ring shaped outer frame is removed. As described above, lead frame 806 shown in FIG. 8A may include an outer frame portion 802 from which leads 204a and 204b (and further leads) inwardly extend. Outer frame portion 802 may be removed from lead frame 806 to separate and isolate leads 204a and 204b from lead frame 806 and from each other. Outer frame 802 may be removed from lead frame 806 in any manner, including by a conventional package singulation technique (e.g., when a panel of lead frames is used). Example techniques include a saw singulation technique, laser cutting, a stamping process, or any other suitable technique mentioned elsewhere herein or otherwise known. When packages are fabricated in a combined panel, the heat spreaders may be separated of the heat spreader panel from each other during step 710 when the ring shaped outer frame is removed by singulating the lead frame panel. For instance, this may occur when cuts are applied to a combined panel, such as combined panels 800 and 820 at dotted lines 808a and 808b (FIG. 8A) or dotted lines 858a and 858b (FIG. 8B), respectively. Such cuts simultaneously remove the ring shaped outer frames from the lead frames, separate leads and heat spreaders from their respective panels to form packages, and form the outer edges of the formed packages (e.g., perimeters edges 238a and 238b in FIGS. 2 and 3) to be planar and perpendicular to the top and bottom surfaces of the formed packages.

As such, it is noted that in embodiments, heat spreaders 206 and 302 and lead frame 806 may each be formed individually, or may be formed in sheets or panels (e.g., lead frame panel 804 and heat spreader panel 812) that include multiple heat spreaders or lead frames according to processes similar to those described above or according to other techniques. An individual lead frame may be attached to an individual heat spreader to form a single package, or a lead frame panel may be attached to a heat spreader panel to form multiple packages in parallel.

### Conclusion

Embodiments are described herein having various shapes, sizes, numbers, and combinations of extended leads (in a lead frame) and pins (in a package). Embodiments may include any number and combination of shapes of the extended leads/pins described herein, and any variations/modifications thereof

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope should not be limited by any of the above-described exemplary embodiments, but should be defined only in accordance with the following claims and their equivalents.

What is claimed is:

1. A die-down quad flat no-lead (QFN) package, comprising:
a heat spreader having opposing first and second surfaces;
a plurality of leads each having a first end portion attached to the first surface of the heat spreader by an electrically insulating adhesive layer and a second end portion;
an integrated circuit (IC) die mounted to the first surface of the heat spreader;
a plurality of wire bonds each having a first end coupled to corresponding pad on an active surface of the IC die and a second end coupled to a corresponding lead of the plurality of leads; and
an encapsulating material that encapsulates the IC die on the heat spreader, the wire bonds, and at least a portion of each of the leads such that the second end portion of each lead extends to a perimeter edge of the encapsulating material.

2. The die-down OFN package of claim 1, comprising:
a second plurality of wire bonds each having a first end coupled to corresponding pad on the active surface of the IC die and a second end coupled to the first surface of the heat spreader.

3. The die-down QFN package of claim 1, further comprising:
a heat sink mounted to the second surface of the heat spreader.

4. The die-down QFN package of claim 1, wherein the heat spreader has a thickness that is greater than a thickness of a lead of the plurality of leads.

5. The die-down QFN package of claim 1, wherein the heat spreader is rectangular in shape, and all four perimeter edges of the heat spreader are covered by the encapsulating material.

6. The die-down QFN package of claim 1, wherein at least one perimeter edge of the heat spreader is co-planar with a perimeter edge of the QFN package.

7. The die-down QFN package of claim 1, wherein at least one perimeter edge of the heat spreader is covered by the encapsulating material.

8. An integrated circuit (IC) package, comprising:
a heat spreader having opposing first and second surfaces;
an electrically insulating adhesive layer attached to the first surface of the heat spreader;
an IC die mounted to the first surface of the heat spreader;
a plurality of leads each having a first end portion attached to a surface of the adhesive layer and a second end portion configured to be connected to a printed circuit board (PCB), the plurality of leads arranged in a ring around the IC die; and
an encapsulating material that encapsulates the IC die on the heat spreader, the plurality of leads, and at least one perimeter edge of the heat spreader such that the second end portion of the each lead is not entirely covered by the encapsulating material.

9. The IC package of claim 8, further comprising:
a first wire bond having a first end coupled to a first pad on an active surface of the IC die and a second end coupled to a first lead of the plurality of leads;

10. The IC package of claim 9, further comprising:
a second wire bond having a first end coupled to a second pad on the active surface of the IC die and a second end coupled to the first surface of the heat spreader.

11. The IC package of claim 8, further comprising:
a heat sink mounted to the second surface of the heat spreader.

12. The IC package of claim 8, wherein the heat spreader has a thickness that is greater than a thickness of the first lead.

13. The IC package of claim 8, wherein the heat spreader is rectangular in shape, and all four perimeter edges of the heat spreader are covered by the encapsulating material.

14. The IC package of claim 8, wherein at least one perimeter edge of the heat spreader is co-planar with a perimeter edge of the IC package.

15. A method for assembling an integrated circuit (IC) package, comprising:
attaching a lead frame to a first surface of a heat spreader with an electrically insulating adhesive layer, the lead frame including an outer ring-shaped frame portion and a plurality of leads that extend inward from outer ring-shaped frame portion, each lead having a first end portion attached to the first surface of the heat spreader by the electrically insulating adhesive layer and a second end portion configured to be mounted to a circuit board;
mounting an IC die to the first surface of the heat spreader;
attaching a plurality of wire bonds between die pads on an active surface of the IC die and the leads of the lead frame;
applying an encapsulating material to encapsulate the IC die, the wire bonds, and a portion of each of the leads on the first surface of the heat spreader; and
removing the outer ring portion of the lead frame to form the IC package.

16. The method of claim 15, wherein said attaching a lead frame to a first surface of a heat spreader with an electrically insulating adhesive layer comprises:
attaching a lead frame panel that includes the lead frame to a heat spreader panel that includes the heat spreader to form a combined panel; and
wherein said removing the outer ring portion of the lead frame comprises:
singulating the combined panel into a plurality of IC packages that includes the IC package.

17. The method of claim 15, further comprising:
covering at least one perimeter edge of the heat spreader with the encapsulating material.

18. The method of claim 15, further comprising:
forming the encapsulating material to have outer edges that are flush with all four perimeter edges of the heat spreader, all four perimeter edges of the heat spreader being exposed to the environment from the IC package.

19. The method of claim 15, wherein the heat spreader has a thickness that is greater than a thickness of the lead frame.

20. The method of claim 15, further comprising:
mounting a heat sink to a second surface of the heat spreader.
